(19) United States
(12) Patent Application Publication
(10) Pub. No.: US 2026/0152518 A1
(43) Pub. Date: Jun. 4, 2026

(54) ORGANOMETALLIC COMPOUND AND METHOD FOR MANUFACTURING METAL RUTHENIUM FILM

(71) Applicant: INDUSTRIAL TECHNOLOGY RESEARCH INSTITUTE, Hsinchu (TW)

(72) Inventors: Zi-Yu Yan, Hsinchu City (TW); Yong-Jay Lee, Hsinchu City (TW); Yu-Chieh Pao, Hsinchu City (TW); Shi-Yen Chen, Taipei City (TW); Po-Yuan Huang, Hsinchu County (TW); Yen-Ju Wu, Kaohsiung City (TW)

(73) Assignee: INDUSTRIAL TECHNOLOGY RESEARCH INSTITUTE, Hsinchu (TW)

(21) Appl. No.: 19/071,215

(22) Filed: Mar. 5, 2025

(30) Foreign Application Priority Data
Dec. 2, 2024 (TW) 113146652

(51) Int. Cl. C07F 15/00; C23C 16/18; C23C 16/455

(52) U.S. Cl. CPC C07F 15/0046; C23C 16/18; C23C 16/45553

(57) ABSTRACT

An organometallic compound having a structure represented by formula (I) and a method for manufacturing a metal ruthenium film are provided.

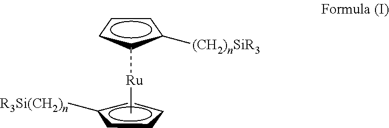

wherein R is C₁-C₆ alkyl; and n is an integer of 1 to 4.

### CROSS-REFERENCE TO RELATED APPLICATION

This non-provisional application claims priority under 35 U.S.C. § 119 (a) to patent application No. 113146652 filed in Taiwan, R.O.C. on Dec. 2, 2024, the entire contents of which are hereby incorporated by reference.

### TECHNICAL FIELD

The technical field relates to an organometallic compound and a method for manufacturing a metal ruthenium film.

### BACKGROUND

In recent years, the functional demand of semiconductor devices has been increasing. Taking dynamic random access memory (DRAM) for example, in order to increase the capacity and in addition to more miniaturization of the structure, it is further necessary to improve the material of an electrode film of the DRAM.

Currently, ruthenium (Ru) is known to have low resistivity, a large work function, high oxidation resistance and the like. Besides, a metal ruthenium film or a ruthenium oxide film can be easily dry-etched, and therefore is suitable as an electrode of a capacitor for dielectrics.

Traditionally, the metal ruthenium film is formed by a sputtering method. However, in recent years, a deposition method has been used to form the metal ruthenium film in order to cope with the more miniaturization structure and productivity.

Chemical vapor deposition (CVD) and atomic layer deposition (ALD) are primary deposition methods for controlled deposition at an atomic level and the formation of very thin coatings. Among them, the ALD is characterized by a series of restrictive surface reactions to control film growth within a monolayer or sub-monolayer thickness range. In other words, the ALD is attracting attention due to its advantages of high step coverage, and capability of precisely controlling film thickness in nanometer or sub-nanometer scale, and ensuring uniformity of the film over a wide range.

An organometallic precursor material used in the ALD needs to be a metal precursor with high purity, high thermal stability and high volatility, and it needs to have a high vapor pressure in order to reduce the process temperature, stabilize the process and reduce the energy consumption.

### SUMMARY

According to one or more embodiments of the present disclosure, an organometallic compound and a method for manufacturing a metal ruthenium film are provided. According to one or more embodiments of the present disclosure, the organometallic compound is a ruthenium compound.

In some embodiments, the present disclosure provides a compound, having the structure represented by formula (I):

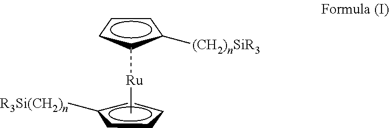

wherein R is C₁-C₆ alkyl; and n is an integer of 1 to 4.

In some embodiments, a method for manufacturing a metal ruthenium film is further provided and forming the metal ruthenium film by forming the compound of the present disclosure on a substrate by a chemical vapor deposition method or an atomic layer deposition method.

To make the foregoing characteristics of the present disclosure more clearly understandable, exemplary implementations are described below with detailed explanations together with the accompanying drawings.

### BRIEF DESCRIPTION OF THE DRAWINGS

FIG. 1 shows a measurement result of differential scanning calorimetry (DSC) of the compound of Example 1;

FIG. 2 shows a measurement result of DSC of the compound of Comparative Example 1;

FIG. 3 shows a measurement result of thermogravimetric analysis (TGA) of the compound of Example 1; and

FIG. 4 shows a measurement result of TGA of the compound of Comparative Example 1.

### DETAILED DESCRIPTION

To enable the objectives, technical features and advantages of the present disclosure to be further understood by those skilled in the art to implement the present disclosure, the technical features and embodiments of the present disclosure are described in the following description in combination with the drawings here and further described by listing embodiments. However, the following embodiments are not used to limit the present disclosure. Besides, the corresponding drawings herein are illustrative of the features of the present disclosure.

### Term Definition and Illustration

In the present description, “C₁-C₆ alkyl” refers to straight-chain and branched-chain alkyls having 1, 2, 3, 4, 5, or 6 carbon atoms. The alkyl is, for example, methyl, ethyl, propyl, butyl, pentyl, hexyl, isopropyl, isobutyl, sec-butyl, tert-butyl, isopentyl, 2-methylbutyl, 1-methylbutyl, 1-ethylpropyl, 1,2-dimethylpropyl, neopentyl, 1,1-dimethylpropyl, 4-methylpentyl, 3-methylpentyl, 2-methylpentyl, 1-methylpentyl, 2-ethylbutyl, 1-ethylbutyl, 3,3-dimethylbutyl, 2,2-dimethylbutyl, 1,1-dimethylbutyl, 2,3-dimethylbutyl, 1,3-dimethylbutyl or 1,2-dimethylbutyl and the like, or an isomer thereof.

In the present description, the elements are also represented by standard symbols of a periodic table, for example, Ru represents ruthenium, Si represents silicon, Co represents cobalt, Ni represents nickel, etc.

In the present description, the abbreviation “Et” refers to ethyl; the abbreviation “TMS” refers to trimethylsilyl; the abbreviation “Cp” refers to cyclopentadienyl; and the abbreviation “Cp—(CH₂)ₙSiR₃” refers to cyclopentadiene having (CH₂)ₙSiR₃ substituents.

### <Compound of the Present Disclosure >

The compound of the present disclosure is a ruthenium compound. According to some embodiments, the ruthenium compound has a low boiling point and a low vaporization temperature, can be effectively used as a precursor for CVD and ALD, and has the structure represented by formula (I):

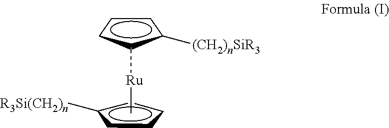

As shown in formula (I), the compound of some embodiments of the present disclosure is a ruthenium metal complex formed by complexing Ru and Cp—(CH₂)ₙSiR₃, wherein n may be an integer of 1, 2, 3 or 4; and R may be a straight-chain or branched-chain alkyl of C₁-C₆.

The structure of the compound of some embodiments of the present disclosure is determined by nuclear magnetic resonance (NMR) analysis. The analysis by NMR is performed using a VARIAN INOVA500 nuclear magnetic resonance spectrometer using deuterated dimethyl sulfoxide (DMSO-d6), deuterated methanol (CD₃OD), deuterated tetrahydrofuran (d8-THF) or deuterated chloroform (CDCl₃) as a solvent and tetramethylsilane as an internal standard.

### Synthesis Example 1

The following illustrates the reaction of the compound of some embodiments of the present disclosure as shown in simplified reaction equation 1 below:

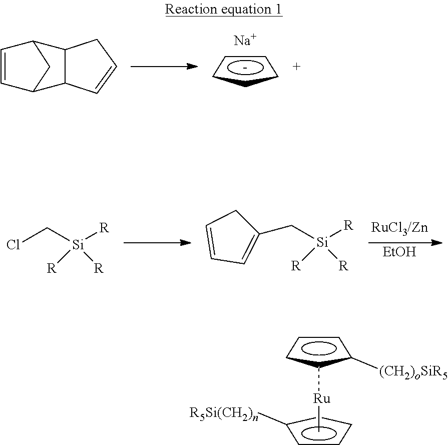

wherein R is C₁-C₆ alkyl and n is an integer of 1 to 4.

In Synthesis example 1 of the compound of the present disclosure, specifically, firstly 400 ml of dicyclopentadiene and 10 g of sodium were heated to 160° C. through a one-pot reaction, and reacted for 6 to 8 hours, then the reaction product was washed with hexane and filtered to obtain sodium cyclopentadienide as a white solid, then 13 ml of the sodium cyclopentadienide was dissolved in 225 ml of anhydrous tetrahydrofuran (dry THF) and cooled to −78° C., 10.4 ml of (chloromethyl)trimethylsilane was dropwise added, and the mixture was warmed to room temperature and stirred for 16 to 24 hours to obtain Cp-CH₂TMS, which was extracted with diethyl ether and purified using a column (SiO₂).

Then an oxide film on the surface of zinc was washed with a hydrochloric acid aqueous solution. 2.4 g of the zinc and 0.8 g of the Cp-CH₂TMS were taken and added into 8 ml of anhydrous ethanol (dry EtOH). Then 0.5 g of RuCl₃ was added into 5 ml of anhydrous ethanol (dry EtOH) in a glove box to dissolve the RuCl₃. The RuCl₃ solution was slowly dropwise added into the mixture of the zinc and the Cp-CH₂TMS at 0° C. to −40° C. for reacting for 16 to 24 hours. The reaction product was separated by a silica gel column chromatography with an eluant of n-hexane, thereby obtaining a final product Ru(Cp-CH₂TMS)₂. The product was analyzed by NMR, and the obtained spectral information was as follows: 1H NMR (500 MHz, CDCl₃, 298 K): 4.334 (s, 4H), 4.302 (s, 4H), 1.561 (s, 4H), 0.024 (s, 18H).

In Synthesis example 1 of the compound of the present disclosure, the yield of the Ru(Cp-CH₂TMS)₂ is about 66%.

### Comparative Synthesis Example 1

Comparative synthesis example 1 is described below, and a simplified reaction equation 2 of comparative synthesis example 1 is shown as follows:

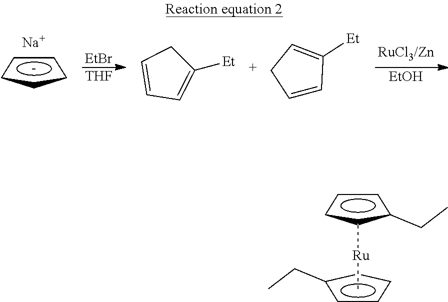

Comparative synthesis example 1, specifically, firstly 400 ml of dicyclopentadiene and 10 g of sodium were heated to 160° C. through a one-pot reaction, and reacted for 6 to 8 hours, then the reaction product was washed with hexane and filtered to obtain sodium cyclopentadienide as a white solid, then 13 ml of the sodium cyclopentadienide was dissolved in 225 ml of anhydrous tetrahydrofuran (dry THF) and cooled to −78° C., bromoethane (EtBr) (25 mmol) was dropwise added to tetrahydrofuran (THF) (10 mL), and the mixture was warmed to room temperature and stirred for 16 to 24 hours to obtain Et-substituted cyclopentadiene, which was extracted with diethyl ether and purified using distillation.

Then an oxide film on the surface of zinc was washed with a hydrochloric acid aqueous solution, 2.4 g of the zinc and an EtCp monomer (5.3 mmol) were added into 8 ml of anhydrous ethanol (dry EtOH). Then 0.5 g of RuCl₃ was added into 5 ml of anhydrous ethanol (dry EtOH) in a glove box to dissolve the RuCl₃. The RuCl₃ solution was slowly dropwise added into the mixture of the zinc and the EtCp monomer at 0° C. to −40° C. for reacting for 16 to 24 hours. The reaction product was filtered by silica gel, thereby obtaining a final product Ru(CpEt)₂. The product was analyzed by NMR, and the obtained spectral information was as follows: 1H NMR (500 MHz, CDCl₃, 298 K): 4.463 (s, 4H), 4.411 (s, 4H), 2.1505 (q, 4H), 1.081 (t, 6H).

The yield of the Ru(CpEt)₂ of Comparative synthesis example 1 is about 80%.

### Comparative Synthesis Example 2

Comparative synthesis example 2 is described below, and a simplified reaction equation 3 of comparative synthesis example 2 is shown as follows:

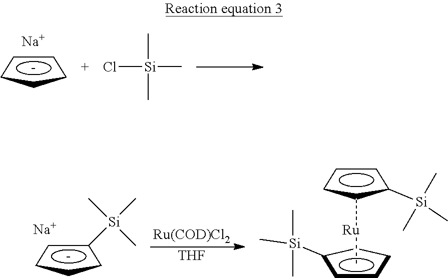

Comparative synthesis example 2 refers to the specification of the patent application TW200420744A. The final product was Ru(Cp-TMS)₂ with a yield of about 13%.

### Examples and Comparative Examples

The final product Ru(Cp-CH₂TMS)₂ obtained by the Synthesis example 1 of the compound of the present disclosure is used as Example 1, the final product Ru(CpEt)₂ obtained by Comparative synthesis example 1 is used as Comparative Example 1, and the final product Ru(Cp-TMS)₂ obtained by Comparative synthesis example 2 is used as Comparative Example 2.

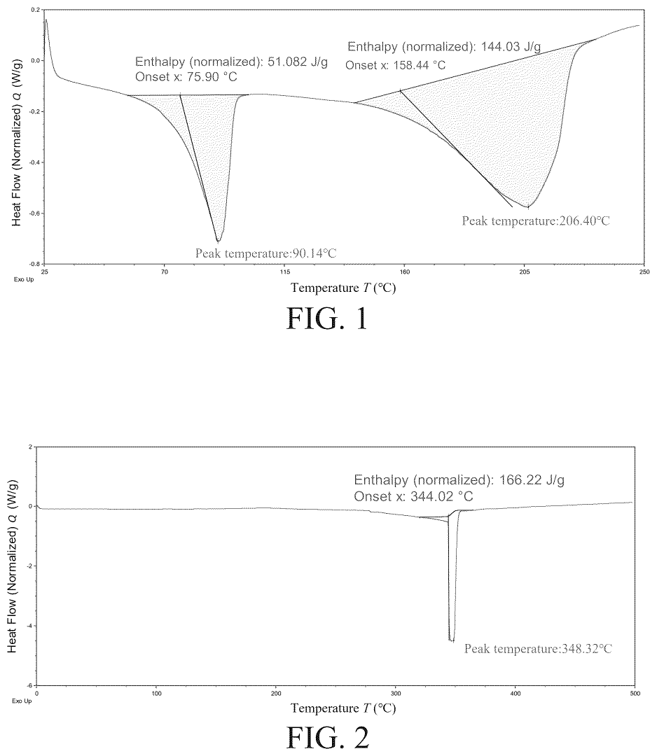

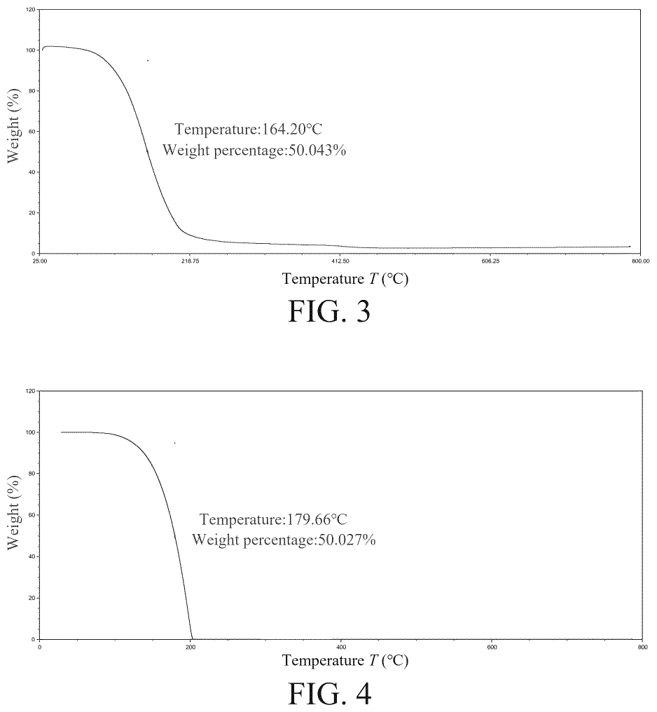

The measurement of boiling points and vaporization temperatures are compared for the final products of Example 1 and Comparative Example 1 as shown in FIGS. 1 to 4. The results are shown in Table 1 below.

### [Measurement of Boiling Point]

The boiling point was measured by differential scanning calorimetry (DSC) using a DSC25 instrument manufactured by Waters Asia Limited.

The final products of Example 1 and Comparative Example 1 were weighed to about 3 to 5 mg, loaded in sample pans, and then encapsulated by an encapsulating press. The final product of Example 1 was a solid, such that a solid sample pan was selected. The final product of Comparative Example 1 was a liquid, such that a liquid sample pan was selected, and the test was performed by the DSC25 instrument.

Measurement conditions:
Example 1: heating to 250.00° C. from 25.00° C. at a ramp rate of 20.00° C./min; and
Comparative Example 1: heating to 500.00° C. from 25.00° C. at a ramp rate of 20.00° C./min.

Measurement results:

The boiling point of the final product of Example 1 is 158° C., the boiling point of the final product of Comparative Example 1 is 344° C., and the boiling point of the final product of Comparative Example 2 is known as 295° C. (see Materials 2010, 3 (2), 1172-1185).

### [Measurement of Vaporization Temperature]

The vaporization temperature was measured by thermogravimetric analyzer (TGA) using a TGA55 instrument manufactured by Waters Asia Limited.

The final product of Example 1 and the final product of Comparative Example 1 were weighed to about 3-5 mg and put into a sample pan of the TGA55 instrument for testing. The measurement condition was: heating to 800.00° C. from 25.00° C. at a ramp rate of 20.00° C./min.

Measurement results:

The temperature of 50% vaporization (50% weight loss) of the final product of Example 1 is 164° C. and the temperature of 50% vaporization of the final product of Comparative Example 1 is 180° C.

TABLE 1

| | Example 1 | Comparative Example 1 | Comparative Example 2 |
|---|---|---|---|
| Final product | 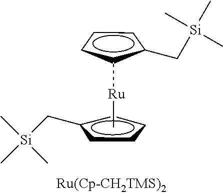 | 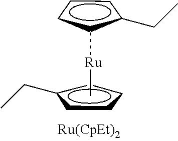 | 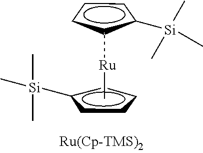 |
| Boiling point | 158 | 344 | 295 |
| (° C.) | | | |
| Temperature | 164 | 180 | — |
| of 50% | | | |
| vaporization | | | |
| (° C.) | | | |

By comparing the final product of Example 1 with the final products of Comparative Examples 1 and 2, it can be known that the compound of some embodiments of the present disclosure has a lower boiling point and vaporization temperature than those of Comparative Examples 1 and 2. Further, even though the molecular weight of the compound of some embodiments of the present disclosure is higher than those of Comparative Examples 1 and 2, the boiling point can be as low as almost half of those of Comparative Examples 1 and 2.

It can be seen from the comparison results that since the compound of some embodiments of the present disclosure contains a Si substituent, and the length between Si and cyclopentadienyl is increased by the presence of a carbon chain therebetween, the intermolecular distance is thus enlarged and the boiling point and the vaporization temperature are reduced.

The compound with a lower boiling point and lower vaporization temperature of some embodiments of the present disclosure is used as a Ru precursor for chemical vapor deposition or atomic layer deposition, which can reduce the energy consumption of the process and is beneficial to the formation of a metal ruthenium film.

The above embodiments are merely for describing the technical ideas and features of the disclosure. The purpose of the embodiments is to enable a person familiar with the art to understand and implement the content of the disclosure. The patent scope of the disclosure certainly cannot be limited by the embodiments. That is, all equivalent changes or modifications made in accordance with the spirit disclosed in the disclosure should fall within the patent application scope of the disclosure.

What is claimed is:

1. A compound, having a structure represented by formula (I): 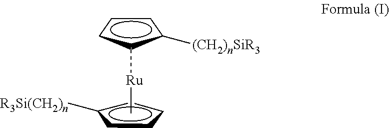
wherein
R is C₁-C₆ alkyl; and
n is an integer of 1 to 4.

2. The compound according to claim 1, wherein n is an integer of 1 to 3.

3. The compound according to claim 1, wherein n is 1 or 2.

4. The compound according to claim 1, having the following structure:

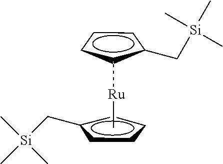

5. A method for manufacturing a metal ruthenium film, comprising forming the metal ruthenium film by forming the compound according to claim 1 on a substrate by a deposition method.

6. The manufacturing method according to claim 5, wherein the deposition method is chemical vapor deposition or atomic layer deposition.
